(19) United States
(12) Patent Application Publication
(10) Pub. No.: US 2025/0324887 A1
(43) Pub. Date: Oct. 16, 2025

(54) DISPLAY PANEL AND DISPLAY DEVICE

(71) Applicants: Hefei Visionox Technology Co., Ltd., Hefei (CN); Visionox Technology Inc., Suzhou (CN)

(72) Inventors: Wenyu ZENG, Hefei (CN); Ying SHEN, Hefei (CN); Pengle DANG, Hefei (CN); Lixiong XU, Hefei (CN); Jingui LIU, Hefei (CN); Shundong BAO, Hefei (CN)

(73) Assignees: Hefei Visionox Technology Co., Ltd., Hefei (CN); Visionox Technology Inc., Suzhou (CN)

(21) Appl. No.: 18/764,374

(22) Filed: Jul. 5, 2024

(30) Foreign Application Priority Data
Apr. 12, 2024 (CN) 202410446702.6

(51) Int. Cl. H10K 59/80; H10K 59/122

(52) U.S. Cl. CPC H10K 59/873; H10K 59/122; H10K 59/871

(57) ABSTRACT

Disclosed are a display panel and a display device, including a display area, an aperture area, and at least one transition area located between the display area and the aperture area. The display panel further includes a substrate and a charge accumulation structure located on the substrate, the charge accumulation structure located on the substrate and located within the transition area, and the charge accumulation structure surrounds at least a portion of the aperture area and is at least partially conductive structure. Within the display panel, a charge accumulation surrounds at least a portion of the aperture area and is at least partially conductive, preventing these charges from propagating to other sections via the substrate, thus avoiding display function quality issues that might otherwise arise in the display panel.

### CROSS-REFERENCE TO RELATED APPLICATIONS

This application claims priority to Chinese patent application No. 202410446702.6, filed on Apr. 12, 2024, which is hereby incorporated by reference in its entirety.

### TECHNICAL FIELD

The present application relates to the field of display technology, and particularly to a display panel and a display device.

### BACKGROUND

Organic Light-Emitting Diodes (OLEDs) is an organic thin-film electroluminescent unit that has garnered significant attention due to its numerous advantages, such as simple manufacturing process, low production costs, low power consumption, high brightness, wide viewing angle, high contrast, and the ability to achieve flexible displays. Consequently, OLEDs are widely implemented in electronic display product.

### SUMMARY

Objectives of the first aspect of the present disclosure provide a display panel, the display panel includes a display area, an aperture area, and at least one transition area located between the display area and the aperture area. The display panel further includes a substrate and a charge accumulation structure located on the substrate, and within the at least one transition area, the charge accumulation structure surrounds at least a portion of the aperture area and is at least partially conductive.

Within the described arrangement, the charge accumulation structure surrounds at least a portion of the aperture area and is at least partially conductive, thereby allowing the accumulation of charges introduced from the aperture area in environments like electrostatic field testing, preventing these charges from propagating to other sections via the substrate, which otherwise may cause display malfunctions in the display panel.

In a specific embodiment of the first aspect of the present disclosure, the substrate includes a base and a driver circuit layer located on the base, at least a portion of the driver circuit layer is located in the display area, and the charge accumulation structure is located on the base.

Within the described arrangement, there are no layers related to the drive circuit between the charge accumulation structure and the base structure. This design effectively decreases the distance between the charge accumulation structure and the base, enabling the charge accumulation structure to accumulate charges directly in close proximity to the base, and further diminishes the likelihood of charges infiltrating into the base and subsequently being directed along it to other sections.

In a specific embodiment of the first aspect of the present disclosure, the charge accumulation surrounds the aperture area.

In a specific embodiment of the first aspect of the present disclosure, the charge accumulation structure includes a plurality of sub-charge accumulation portions, and the sub-charge accumulation portions are spaced apart from each other and surround the aperture area sequentially along a direction away from the aperture area. Thus, the design area of the charge accumulation structure can be increased, thereby enhancing the charge accumulation capacity of the charge accumulation structure. Furthermore, these sub-charge accumulation portions spacing apart mitigate stress transmission between each other, thereby reducing the likelihood of stress concentration within the charge accumulation structure.

In a specific embodiment of the first aspect of the present disclosure, the charge accumulation structure further includes at least one connecting portion, and at least one connection portion is conductive, and each connecting portion of the at least one connection portion is located between adjacent sub-charge accumulation portions of the plurality of sub-charge accumulation portions. Therefore, by electrically connecting each sub-charge accumulation portions with one another, the overall charge accumulation capacity of the charge accumulation structure can be enhanced, while preventing issues such as electrostatic breakdown caused by excessive charge concentration in local areas of the charge accumulation structure.

In a specific embodiment of the first aspect of the present disclosure, the sub-charge accumulation portions include a mesh-like structure. This approach may further facilitate stress release, reducing the risk of stress concentration in the charge accumulation structure.

In a specific embodiment of the first aspect of the present disclosure, the plurality of sub-charge accumulation portions include two to five sub-charge accumulation portions.

In a specific embodiment of the first aspect of the present disclosure, the display panel further includes a first encapsulation layer, a second encapsulation layer, and a third encapsulation layer stacked on the substrate sequentially. Each of the first encapsulation layer and the third encapsulation layer includes an inorganic layer, the second encapsulation layer includes an organic layer, the first encapsulation layer and the second encapsulation layer are located in the display area and in the at least one transition area, the third encapsulation layer is located in the display area and in the transition area, and the third encapsulation layer covers the charge accumulation structure on one side, away from the substrate, of the charge accumulation structure and covers a gap between each two of the plurality of the sub-charge accumulation portions.

Within the described arrangement, the third encapsulation layer is deposited within the gaps between the sub-charge accumulation portions, allowing for better anchoring (either directly or indirectly) of the third encapsulation layer to the substrate. This arrangement improves the encapsulation efficiency of the display panel.

In a specific embodiment of the first aspect of the present disclosure, the second encapsulation layer is located in an edge region of the transition area.

In a specific embodiment of the first aspect of the present disclosure, the first encapsulation layer covers at least a portion of the charge accumulation structure on one side of the charge accumulation structure away from the substrate. Therefore, the first encapsulation layer and the charge accumulation structure ensures a seamless integration. When forming the third encapsulation layer subsequently, this arrangement facilitates the anchoring of the third encapsulation layer to the charge accumulation structure via the first encapsulation layer, thereby further enhancing the encapsulation efficacy of the display panel.

In a specific embodiment of the first aspect of the present disclosure, the display panel further includes a pixel-defining layer located in the display area and the at least one transition area. Within the transition area, the pixel-defining layer is located between the charge accumulation structure and the base, and the pixel-defining layer includes an inorganic layer.

In a specific embodiment of the first aspect of the present disclosure, the third encapsulation layer is in contact with the pixel-defining layer at the gaps between adjacent sub-charge accumulation portions of the plurality of the sub-charge accumulation portions. Therefore, the third encapsulation layer can be anchored to the substrate via the pixel-defining layer. Both of the pixel-defining layer and the third encapsulation layer are inorganic film layers with inherent strong bonding force between each other, which significantly decreases the risk of delamination of the third encapsulation layer, further enhancing the encapsulation effectiveness of the display panel.

In a specific embodiment of the first aspect of the present disclosure, the display panel further includes at least one dam, the at least one dam is located between the display area and the charge accumulation structure, and is located between the substrate and the pixel-defining layer. The charge accumulation structure may operate like a dam, impeding any overflow of the liquid bypassing the dam during the display panel fabrication process (employed in forming the second encapsulation layer). This charge accumulation structure may reduce the quantity of dams required.

In a specific embodiment of the first aspect of the present disclosure, the display panel further includes a display function layer and an isolation structure located on the substrate. The display function layer includes light-emitting units located in the display area, the isolation structure is located in the display area and enclosures a plurality of isolated openings, and at least a portion of the light-emitting units are located within the plurality of isolated openings.

In a specific embodiment of the first aspect of the present disclosure, the isolation structure and at least a portion of the charge accumulation structure and are in the same layer and made of the same material.

Within the described arrangement, at least a portion of the charge accumulation structure can be fabricated simultaneously when fabricating the isolation structure, thereby reducing or avoiding additional manufacturing process of the display panel caused by the arrangement of the charge accumulation structure, thereby lowering the production cost of the display panel.

In a specific embodiment of the first aspect of the present disclosure, an orthogonal projection of an end portion, toward the substrate, of the isolation structure on the substrate is located within an orthogonal projection of an end portion, away from the substrate, of the isolation structure on the substrate.

Within the described arrangement, the isolation structure exhibits a wider width at the top and narrows down towards the bottom, thereby constraining the deposition area of the deposited films during the fabrication of light-emitting units, and thus ensuring the electrical functionality of light-emitting units (such as the connection of the second electrode described in the following), simultaneously, serving to partition certain films within the light-emitting units (such as the first light-emitting function layer as described in the following).

In a specific embodiment of the first aspect of the present disclosure, an orthogonal projection of an end portion, toward the substrate, of the charge accumulation structure on the substrate is located within an orthogonal projection of an end portion, away from the substrate, of the charge accumulation structure on the substrate.

In a specific embodiment of the first aspect of the present disclosure, the isolation structure includes a first support portion and a first crown portion, the first support portion is located between the first crown portion and the substrate, and an orthogonal projection of the first support portion on the substrate is located within an orthogonal projection of the first crown portion on the substrate; the charge accumulation structure includes a second support portion and a second crown portion, the second support portion is located between the second crown portion and the substrate, and an orthogonal projection of the second support portion on the substrate is located within an orthogonal projection of the second crown portion on the substrate.

In a specific embodiment of the first aspect of the present disclosure, at least a portion of each of the first support portion and the second support portion is a conductive structure.

In a specific embodiment of the first aspect of the present disclosure, the first support portion and the second support portion are in a same layer and made of same material; and/or, the first crown portion and the second crown portion are in a same layer and made of same material.

In a specific embodiment of the first aspect of the present disclosure, each of the light-emitting unit includes a first electrode, a first light-emitting function layer, and a second electrode stacked sequentially on the substrate, the first light-emitting function layer and the second electrode are located within the plurality of isolated openings, and the second electrode is connected to the first support portion.

In a specific embodiment of the first aspect of the present disclosure, the charge accumulation structure includes a plurality of sub-charge accumulation portions, the plurality of sub-charge accumulation portions are spaced apart from each other and surrounding the aperture area sequentially along a direction away from the aperture area, the sub-charge accumulation portion includes a mesh-like structure. A second light-emitting functional layer and a third electrode are disposed in each of mesh holes of the mesh-like structure of each of the plurality of sub-charge accumulation portions, and the third electrode is connected to the second support portion. Therefore, each mesh hole of the sub-charge accumulation portion are further covered by the third electrode, and the sub-charge accumulation portion is connected to the third electrode. This arrangement enables the third electrode to participate in charge accumulation, thereby further enhancing the charge accumulation capability in the vicinity of the aperture area.

In a specific embodiment of the first aspect of the present disclosure, the charge accumulation structure further includes at least one connecting portion, the at least one connecting portion is conductive, and each connecting portion of the at least one connecting portion is located between adjacent sub-charge accumulation portions of the plurality of sub-charge accumulation portions and is connected to the sub-charge accumulation portions adjacent to the connecting portion.

In a specific embodiment of the first aspect of the present disclosure, the connecting portion is in same layer and made of same material as at least one of the first support portion and/or the second electrode.

In a specific embodiment of the first aspect of the present disclosure, the display panel further includes a first encapsulation layer covering the isolation structure and the charge accumulation structure, the first encapsulation layer includes a plurality of encapsulation units spaced apart from each other, the encapsulation units correspond to the isolated openings and the mesh holes respectively, and cover the isolated openings and the mesh holes corresponding to the encapsulation units.

In a specific embodiment of the first aspect of the present disclosure, each two adjacent encapsulation units, located on the same isolation structure, are spaced apart.

In a specific embodiment of the first aspect of the present disclosure, the first support portion includes a first sub-support layer and a second sub-support layer, the first sub-support layer is located between the second sub-support layer and the substrate, the second sub-support layer is located between the first sub-support layer and the first crown portion, and an orthogonal projection of the second sub-support layer on the substrate is located within an orthogonal projection of the first sub-support layer on the substrate.

In a specific embodiment of the first aspect of the present disclosure, the second support portion includes a third sub-support layer and a fourth sub-support layer, the third sub-support layer is located between the fourth sub-support layer and the substrate, the fourth sub-support layer is located between the third sub-support layer and the second crown portion, and an orthogonal projection of the fourth sub-support layer on the substrate is located within an orthogonal projection of the third sub-support layer on the substrate.

Within the described arrangement, a portion of surface of the first sub-support portion, away from the substrate, that is not covered by the second sub-support portion can be used to contact the second electrode, and allows for a greater deposition thickness of the second electrode on the first sub-support portion, so as to effectively reduces the resistance in the connection between the second electrode and the first support portion; correspondingly, a portion of surface of the third sub-support portion, away from the substration, that is not covered by the fourth sub-support portion can be used to contact with the third electrode, and allows for a greater deposition thickness of the third electrode on the third sub-support portion, so as to effectively reduces the resistance in the connection between the third electrode and the third sub-support portion.

In a specific embodiment of the first aspect of the present disclosure, the display panel can further include a pixel-defining layer, the pixel-defining layer is located in the display area and in the transition area, the pixel-defining layer is located between the isolation structure and the substrate, and the pixel-defining layer is located between the charge accumulation structure and the substrate. In the display area, the pixel-defining layer enclosures a plurality of pixel openings, at least some of the plurality of pixel openings delimit the light-emitting units, and the pixel openings and the isolated openings delimit the same light-emitting units are connected to each other.

In a specific embodiment of the first aspect of the present disclosure, the pixel-defining layer includes an inorganic layer.

Within the described arrangement, the pixel-defining layer enables the first electrode to have a larger design area, thereby increasing the light-emitting area of the light-emitting unit.

The second aspect of the present disclosure provides a display panel, the display panel includes a display area, an aperture area, and at least one transition area located between the display area and the aperture area, and the display panel further includes a substrate, a charge accumulation structure, a display function layer, and an isolation structure. The charge accumulation structure is located on the substrate and within the at least one transition area, and the charge accumulation structure surrounds at least a portion of the aperture area and is at least partially conductive; the display function layer is located on the substrate and included a plurality of light-emitting units located in the display area; and the isolation structure is located in the display area and on the substrate, the isolation structure enclosed a plurality of isolated openings, and at least a portion of each of the plurality of light-emitting units is located within the plurality of isolated openings.

The third aspect of the present disclosure provides a display device, which includes the display panel of any embodiment in the first aspect and the second aspect within the described arrangement.

### BRIEF DESCRIPTION OF THE DRAWINGS

The present of FIG. 1 is a schematic diagram of a planar structure of a display panel according to an embodiment of the present disclosure.

FIG. 2A is an enlarged view of the S1 region of the display panel shown in FIG. 1.

FIG. 2B is an enlarged view of the transition area and aperture area of the display panel shown in FIG. 1 in one design.

FIG. 3A is a sectional view along M1-N1 of the display panel shown in FIG. 2A in one design.

FIG. 3B is a sectional view along M2-N2 of the display panel shown in FIG. 2B in one design.

FIG. 4A is a schematic diagram of the further designed structure of the display panel shown in FIG. 3A.

FIG. 4B is a schematic diagram of the further designed structure of the display panel shown in FIG. 3B.

FIG. 5A is an enlarged view of the transition area and aperture area of the display panel shown in FIG. 1 in another design.

FIG. 5B is a sectional view along M3-N3 of the display panel shown in FIG. 5A.

FIG. 6A is a sectional view along M1-N1 of the display panel shown in FIG. 2A in one design.

FIG. 6B is a sectional view along M2-N2 of the display panel shown in FIG. 2B in another design.

FIGS. 7 to 10 are process diagrams of a preparation method for forming a display panel as shown in FIGS. 3A and 3B according to an embodiment of the present disclosure.

Explanation of reference marks in the figures:

10—display panel; 11a—display area; 11b—aperture area; 11c—transition area; 12—border area; 100—substrate; 110—base; 200—light emitting unit; 210—first electrode; 220—first light emitting function layer; 221—first function layer; 222—light emitting layer; 223—second function layer; 230—second electrode; 220a—second light emitting function layer; 230a—third electrode; 300—isolation structure; 300a—charge accumulation structure; 31a, 31b—sub-charge accumulation portion; 301—isolated opening; 301a—isolated opening; 302—pixel opening; 310—first support portion; 311—first sub-support layer; 312—second sub-support layer; 313—connection portion; 320—first crown portion; 310a—second support portion; 311a—third sub-support layer; 312a—fourth sub-support layer; 320a—second crown portion; 330—pixel-defining layer; 510—first encapsulation layer; 510a—first encapsulation film; 511—encapsulation unit; 520—second encapsulation layer; 530—third encapsulation layer; 600—photoresist pattern.

### DETAILED DESCRIPTIONS OF THE EMBODIMENTS

Implementations of the details of the technical solutions according to embodiments of the present disclosure will be elucidated clearly and comprehensively in conjunction with the attached drawings in the following embodiments. Obviously, these described embodiments represent merely a part of the possible embodiments of the present disclosure, not an exhaustive list. Any and all alternative embodiments derived by a person of ordinary skill in the art without requiring inventive effort, based on the embodiments disclosed herein, fall within the scope of protection of this disclosure.

During the development of the present invention, the inventors encountered the following issues with existing technology: In the arrangement of display panels, an aperture area is incorporated to accommodate functionalities such as a camera. However, the presence of this aperture area adversely affects the display performance of the panel.

This disclosure presents at least one embodiment in the form of a display panel and a display device, aimed at addressing the aforementioned technical challenges. The display panel includes a display area, an aperture area, and at least one transition area located between the display area and the aperture area. The display panel further includes a substrate and a charge accumulation structure located on the substrate, and within the at least one transition area, the charge accumulation structure surrounds at least a portion of the aperture area and is at least partially conductive structure. In the display panel, the charge accumulation structure with conductive function surrounds at least a portion of the aperture area. Thus, even under conditions like electrostatic field testing where charges may infiltrate the aperture area, the charge accumulation structure can direct charges to guide the charges from the aperture area into the charge accumulation structure. By accumulating the charges, the charge accumulation structure prevents their transmission through the substrate and subsequent interference with other components (for example, the structure of conductive charges such as the base included in the substrate such as base substrate conductive structures the display panel included), thereby avoiding any display malfunctions and other issues in the display panel.

Further details on the composition, preparation, and additional aspects of the isolation structure are extensively covered in the patents PCT/CN2023/134518, 202310759370.2, 202310740412.8, 202310707209.0, 202311346196.5, 202310771071.0, 202311117143.6, 202310692671.8, 202410110015.7, 202310773656.6 for reference.

Then, the structure of the display panel in accordance with at least one embodiment of the present disclosure will be meticulously explained with reference to the attached figures. In addition, in these figures, a Cartesian coordinate system is established in three-dimensional space using the substrate as the basis, facilitating a more intuitively presentation of the relative positioning of the panel's components. In this spatial Cartesian coordinate system, the X and Y axes align with the substrate's surface, while the Z axis is orthogonal to the substrate's surface.

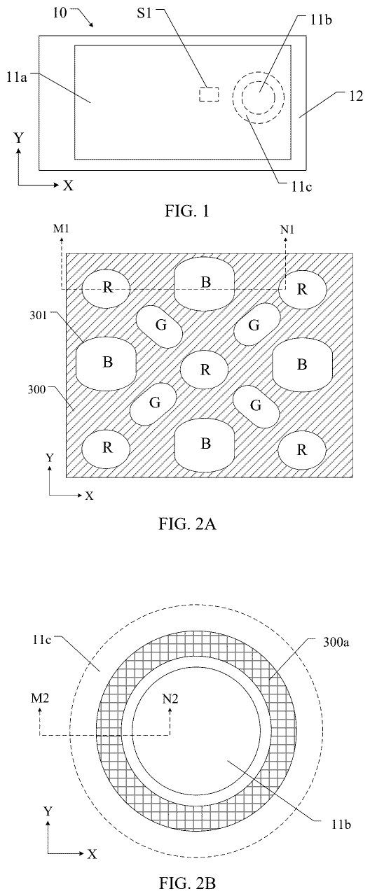

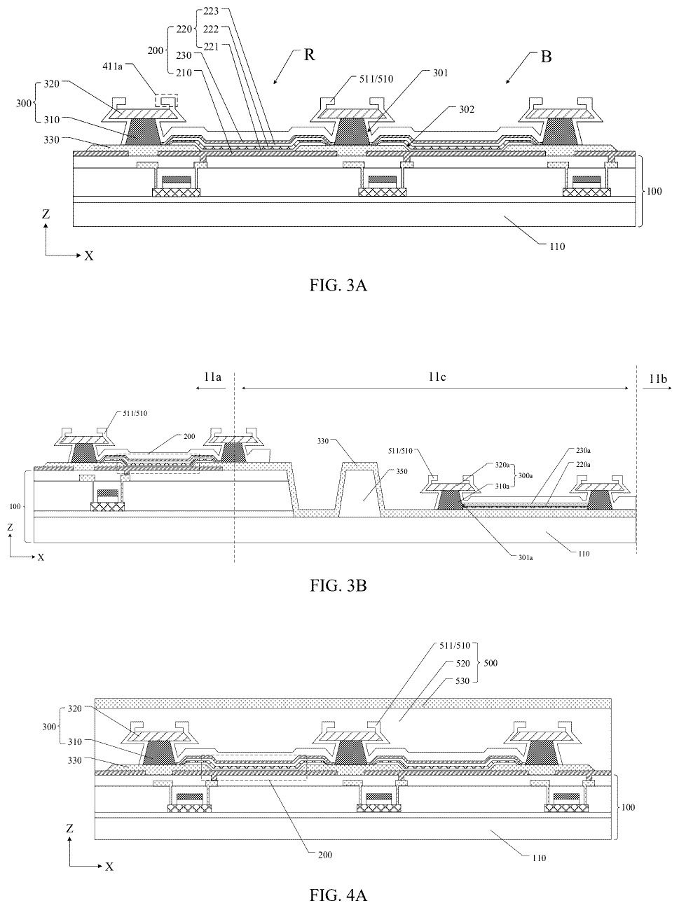

As shown in FIG. 1, FIG. 2B, FIG. 3A, and FIG. 3B, the planar expanse of the display panel 10 can be sectioned into a display area 11a and a border area 12 that surrounds the display area 11a. The aperture area 11b and the transition area 11c are arranged inside the display area 11a, the transitional area 11c is located between the display area 11a and the aperture area 11b, and the transitional area 11c surrounds the aperture area 11b. Sub-pixels (further known as Sub-pixels, etc.) can be arranged in the display area 11a, such as R, G, and B Sub-pixels. The physical structure of the sub-pixel can be a light-emitting unit, and adjacent Sub-pixels with different light-emitting colors constitute a pixel (further known as a pixel unit, a large pixel, etc.). The arrangement density of the pixel in the display area 11a represents the pixel density PPI.

It should be noted that the border area 12 does not need to entirely surround the display area 11a. In some embodiments of this disclosure, portions of the wire within the border area 12 may be arranged into the display area 11a, thereby allowing a border area 12 to be designed as a single-sided border.

It should be noted that in the embodiments presented disclosure, the placement of the aperture area is unrestricted and can be tailored to the specific planar configuration of the display panel. For example, the aperture area can also be positioned on one side of the display area, meaning the aperture area does not need to be completely surrounded by the display area.

The physical structure of the display panel 10 can include a substrate 100 and a charge accumulation structure 300a located on the substrate 100. The charge accumulation structure 300a is located on the substrate 100 and within the transition area 11c, and the charge accumulation structure 300a surrounds at least a portion of the aperture area 11b and is at least partially conductive. Thus, when charges conduct downward from the aperture area 11b, they will be preferentially accumulated by the conductive charge accumulation structure 300a.

In at least one embodiment of the present disclosure, the charge accumulation structure 300a surrounds the aperture area 11b.

In at least one embodiment of the present disclosure, as shown in FIG. 3A and FIG. 3B, the substrate 100 includes a base 110 and a drive circuit layer located on the base 110. At least a portion of the drive circuit layer is located in the display area 11a, and the charge accumulation structure 300a is located on the base 110. Thus, in the absence of obstruction of drive circuit-related film layers between the charge accumulation structure 300a and the base 110, the distance between the charge accumulation structure 300a and the base 110 is reduced. This enables the charge accumulation structure 300a to directly accumulate charges in close proximity to the base 110, further diminishing the likelihood of charges infiltrating into the base 110 and conducted along the base 110 to other areas.

For example, the drive circuit layer includes a plurality of pixel drive circuits located in the display area 11a, and the display function layer is located on the drive circuit layer, and the display function layer includes light-emitting units. For example, the pixel drive circuit may include multiple transistors TFT, capacitors, etc., and can be formed in 2T1C (i.e., two transistors (TFT) and one capacitor (C)), 3T1C or 7T1C and other forms. The pixel drive circuit is connected to the light-emitting unit in the display area 11a to control the on/off state of the light-emitting unit and luminous brightness of the light-emitting unit.

The drive circuit layer includes a buffer layer, an inter-layer dielectric layer, a gate-insulating layer, a flattening layer, and a plurality of metal layers, and the inter-layer dielectric layer, the gate-insulating layer, and the flattening layer can be arranged with one layer or multiple layers. These film layers can be located in the display area and extend to the transition area, but these film layers can not be set in the area of the transition area in close proximity to the aperture area. Thus, during the formation of apertures (such as via cutting) in the aperture area, the likelihood of cracks in these film layers and any potential for cracks to propagate under cutting stress towards the display area 11a can be avoided, which could inflict damage to the panel's film layers. It should be noted that these aforementioned metal layers facilitate the fabrication of capacitors, signal wires, and gate electrodes, source-drain electrodes, etc. in transistor TFT technology.

It should be noted that in the embodiments of the present disclosure, the charge accumulation structure 300a is configured only to surround the aperture area, effectively accumulating charges in this vicinity. Its precise configuration and shape can be tailored to meet the specific demands of the manufacturing process. In the following, several illustrative designs for the charge accumulation structure 300a will be outlined.

In some embodiments of the present disclosure, the charge accumulation structure 300a may be configured as an independent continuous structure (integrated structure). For example, as shown in FIG. 2B and FIG. 3B, an orthogonal projection of the charge accumulation structure 300a on the base 110 is a closed annular structure. For example, the shape of an orthogonal projection of the charge accumulation structure 300a on the base 110 is conformal with the shape of an orthogonal projection of the transition area on the surface where the base 110 is located, for example, further, both shapes are annular.

In some embodiments of the present disclosure, as shown in FIG. 5A and FIG. 5B, the charge accumulation structure 300a includes a plurality of sub-charge accumulation portions (FIG. 5A shows two sub-charge accumulation portions 31a and 31b), the sub-charge accumulation portions 31a and 31b are spaced apart and surround the aperture area 11b from the inside to the outside sequentially (along a direction from the aperture area to away from the aperture area). Thus, the design area of the charge accumulation structure 300a is expanded, bolstering the charge accumulation capability of the charge accumulation structure 300a. Furthermore, the sub-charge accumulation portions 31a and 31b are spaced apart from each other with reduced stress transmission between them, thereby reducing the likelihood of stress localization within the charge accumulation structure 300a. For example, an orthogonal projection of the sub-charge accumulation portions 31a and 31b on the surface where the base 110 is located may be a concentric annular pattern.

In at least one embodiment of the present disclosure, as shown in FIG. 5A, the charge accumulation structure 300a further includes at least one conductive connection portion 313, the connection portion 313 is located between adjacent sub-charge accumulation portions 31a and sub-charge accumulation portion 31b, and is connected to adjacent sub-charge accumulation portions 31a and sub-charge accumulation portion 31b. Thus, the sub-charge accumulation portions 31a and 31b are connected with each other, further boosting the charge accumulation capacity of the charge accumulation structure 300a, and preventing charges excessively concentrating in local areas of the charge accumulation structure 300a, thereby avoiding issues such as electrostatic breakdown. For example, a portion of charge on sub-charge accumulation portion 31a can be channeled to sub-charge accumulation portion 31b, reducing the voltage on sub-charge accumulation portion 31a, thereby diminishing the likelihood of the electrostatic breakdown that may be caused by excessive voltage on sub-charge accumulation portion 31a.

In some embodiments of the present disclosure, as shown in FIG. 3A to FIG. 5B, the charge accumulation structure 300a can be designed to include a mesh-like structure, so as to facilitate stress release and reduce the risk of stress concentration in the charge accumulation structure 300a. Specifically, as shown in FIG. 5A and FIG. 5B, the sub-charge accumulation portions 31a and 31b include a mesh-like structure.

In some other embodiments of the present disclosure, the charge accumulation structure or sub-charge accumulation portion can be configured as a continuous film layer structure (devoid of pores, mesh holes, or similar features).

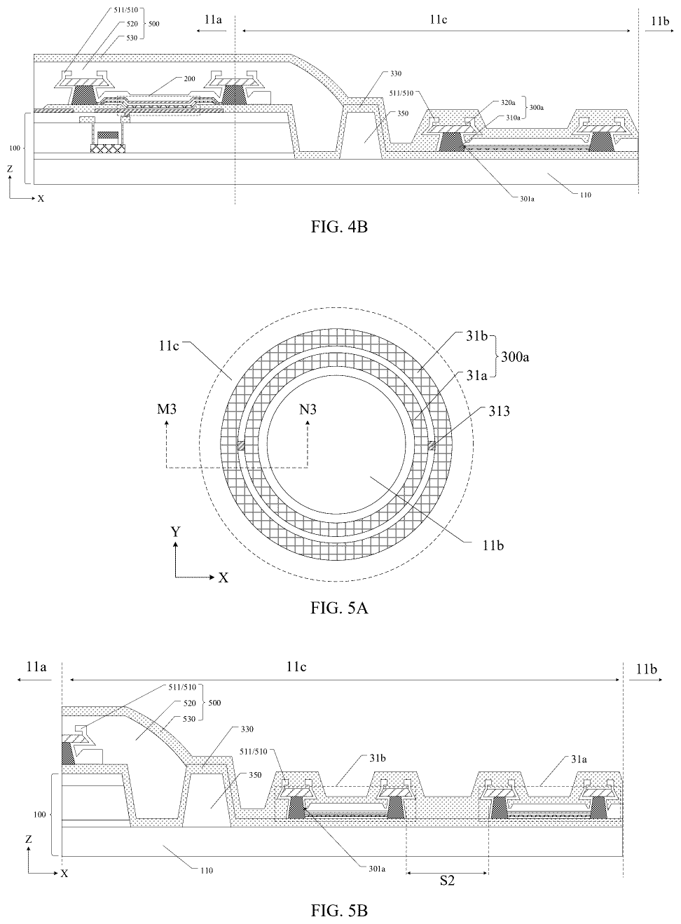

In at least one embodiment of the present disclosure, as shown in FIG. 4A, FIG. 4B and FIG. 5B, the display panel further includes a first encapsulation layer 510, a second encapsulation layer 520 and a third encapsulation layer 530 stacked on the substrate 100 sequentially. Each of the first encapsulation layer 510 and the third encapsulation layer 530 includes an inorganic layer, and the second encapsulation layer 520 includes an organic layer. The first encapsulation layer 510 and the second encapsulation layer 520 are located in the display area 11a (for example, covering the display area 11a) and in the at least one transition area 11c, and the third encapsulation layer 530 is located in the display area 11a and in the transition area 11c. The encapsulation layer 500 composed of the first encapsulation layer 510, the second encapsulation layer 520 and the third encapsulation layer 530 can encapsulate the display area and the transition area, aiming to maintain encapsulation effectiveness of the display panel after the aperture arranged in the aperture area is created.

In at least one embodiment of the present disclosure, the second encapsulation layer 520 is located in the edge region of the transition area 11c, specifically is on one side proximity to the display area 11a in the edge region of the transition area 11c. Specifically, the dimensions of the edge region can be tailored according to the actual situation.

In at least one embodiment of the present disclosure, as shown in FIG. 5B, the third encapsulation layer 530 covers the charge accumulation structure 300a on one side, away from the substrate 100, of the charge accumulation structure 300a and covers a gap between the sub-charge accumulation portions 31a and 31b (the area shown in S2). Thus, the third encapsulation layer 530 can be deposited within the gap between the sub-charge accumulation portions 31a and 31b, allowing for better anchoring (either directly or indirectly) of the third encapsulation layer 530 to the substrate 100, preventing detachment from the substrate 100 and thereby enhancing the encapsulation efficacy of the display panel; in addition, in the case of the presence of cracks in the third encapsulation layer 530, the gap between the sub-charge accumulation portions 31a and 31b may act as a barrier, impeding crack propagation. The underlying principle includes at least: within this gap, each of the sub-charge accumulation portion 31a and 31b creates a groove-like space which may alter direction of crack propagation, increasing the difficulty of crack extension, increasing the path of crack propagation, etc., thereby impeding the propagation of cracks.

It should be noted that in the embodiments of the present disclosure, the plurality of sub-charge accumulation units is not fixed and can be tailored to specific requirements. In certain embodiments of this disclosure, for instance, the plurality of sub-charge accumulation units may include two to five sub-charge accumulation portions, specifically including two, three, four, or five sub-charge accumulation portions. This balance optimizes the charge accumulation structure, maintaining charge accumulation efficiency while minimizing the charge accumulation structure area, thereby enabling a more compact design of the transition area.

In some embodiments of the present disclosure, the charge accumulation structure can be directly arranged on the base of the substrate, meaning the charge accumulation structure has direct contact with the base. Thus, within the gap of the sub-charge accumulation portions, the third encapsulation layer can come into contact with the base.

It should be noted that in at least one embodiment of the present disclosure, the base may include organic materials to provide a certain degree of flexibility. Correspondingly, the insulation capability of the base, as charges accumulated on the base may potentially conducted through the base.

In some other embodiments of the present disclosure, the first encapsulation layer 510 covers at least part of the charge accumulation structure 300a on one side, away from the substrate 100 of the charge accumulation structure 300a. Therefore, the first encapsulation layer 510 may have a seamless integration with the charge accumulation structure 300a. When forming the third encapsulation layer 530 subsequently, the third encapsulation layer 530 may be anchored to the charge accumulation structure 300a via the first encapsulation layer 510, thereby enhancing the encapsulation efficiency of the display panel.

In at least one embodiment of the present disclosure, as shown in FIG. 5A and FIG. 5B, the display panel can further include a pixel-defining layer 330, and the pixel defining layer 330 is located in the display area 11a and the transition area 11c. In the transition area 11c, the pixel defining layer 330 is located between the charge accumulation structure 300a and the base 110, and the pixel defining layer 330 includes an inorganic layer.

It should be noted that the phrase “the pixel defining layer includes an inorganic layer” implies: the pixel defining layer includes at least two film layers, with at least one being an inorganic layer; or, the pixel defining layer being an inorganic layer, which might be a singular film layer or a multi-layer lamination construct made up of a plurality of film layers.

In at least one embodiment of the present disclosure, as shown in FIG. 5A and FIG. 5B, in the gap between adjacent sub-charge accumulation portions 31a and 31b, the third encapsulation layer 530 is in contact with the pixel defining layer 330. Therefore, the third encapsulation layer 530 is anchored to the substrate 100 via the pixel defining layer 330. Both the pixel defining layer 330 and the third encapsulation layer 530 are inorganic film layers with inherent strong bonding force between each other, which significantly reduces the risk of delamination of the third encapsulation layer 530, further enhancing the encapsulation efficiency of the display panel. It should be noted that within the transition area, the sequence involves the formation of the pixel defining layer 330 directly on the base 110, preceding the formation of the charge accumulation structure 300a. Thus, the pixel defining layer 330 exerts a strong bond with the base 110. Thus, after the formation of the charge accumulation structure 300a, the third encapsulation layer 530 is bonded to the pixel defining layer 330. Both of the third encapsulation layer 530 and the pixel defining layer 330, being of the same inorganic nature, exhibit significant bonding strength. Therefore, despite the restricted bonding area between the third encapsulation layer 530 and the base 110, imposed by the existing of the charge accumulation structure 300a, the third encapsulation layer 530 is firmly anchored to the base via the pixel defining layer 330.

In at least one embodiment of the present disclosure, as shown in FIG. 5B, the display panel can further include at least one dam 350, and the dam 350 is located between the charge accumulation structure 300a of the display area 11a and the transition area 11c, and is located between the substrate 100 and the pixel defining layer 330. The dam 350 serves to elongate the extent of the pixel defining layer 330, effectively curtailing crack progression within the pixel defining layer 330 in the presence of a crack, thereby protecting the structure of the display region; in addition, during the fabrication of the second encapsulation layer 520, the dam 350 acts as a barrier preventing the flow of the encapsulating medium (such as ink used in ink-jet printing and other ways) from the subsequent formation of the second encapsulation layer 520 extending towards the aperture area. This ensures that the second encapsulation layer 520 can be completely covered by the third encapsulation layer 530, thereby enhancing the overall encapsulation effectiveness of encapsulation layer 500. The charge accumulation structure 300a acts as a dam 350, preventing the flow of the encapsulating medium that might bypass the dam 350 during panel manufacturing (used to fabricate the second encapsulation layer), thereby potentially reducing the quantity of the dam 350 required.

It should be noted that in the embodiments of the present disclosure, there is no restriction on the quantity of dams 350 arranged, which can be designed in accordance with requirements of the actual process. For example, the dam 350 can be configured with two instances as depicted in FIG. 5B, or even a single instance, thereby minimizing the area it occupies. This economization of space allows for a more compact design of transition area.

In at least one embodiment of the present disclosure, the dam 350 can be fabricated separately, or as shown in FIG. 5B, at least part of the dam 350 can be fabricated simultaneously during the fabrication process of the driver circuit layer. For example, the driver circuit layer can include a buffer layer, an inter-layer dielectric layer, a gate-insulating layer, and a flatting layer, and the dam 350 is in the same layer and made of the same material as the buffer layer, inter-layer dielectric layer, gate-insulating layer, and flatting layer, meaning the dam 350 is formed simultaneously during the fabrication process of the buffer layer, inter-layer dielectric layer, gate-insulating layer, and flatting layer.

It should be noted that in the region from the edge of the charge accumulation structure 300a to the display area 11a, there is no presence of any organic film layer or metal film layer that extends from the transitional area 11c into the display area 11a. This feature effectively ensures the encapsulation efficiency of the display panel and thereby significantly enhances the performance of the display panel.

In the application scenarios of display panels, there are high demands for high pixel densities (PPI). Isolation structures are arranged in the display area, with light-emitting units fabricated correspondingly based on these isolation structures. This fabrication methodology boasts high precision in fabricating light-emitting units, translating to exceedingly high PPI values. Based on this application scenario, at least one embodiment of the present disclosure, at least a portion of the charge accumulation structure can be fabricated simultaneously in the process of fabricating the isolation structure. This strategy aims to simplify the fabrication process of the display panel, thereby economizing manufacturing costs.

The following will provide an explanation of the application specifications, the configuration method details, the process mode of auxiliary fabrication of light-emitting units, and an elucidation of the principle behind enhancing pixel PPI for the isolation structure, so as to concurrently describe the precise configuration approach for the charge accumulation structure and the isolation structure which are fabricated simultaneously.

In the display panel, several functional film layers in the light-emitting unit are fabricated through vapor deposition processes. These light-emitting units encompass a multitude of functional film layers, with some (such as the emissive layer) functional film layers in the light-emitting units emitting different light rays may have different composition. Therefore, when depositing these layers via mask techniques (fine metal masks), multiple precise alignments are required. To address positional deviations arising from alignment inaccuracies, sufficient spacing should be reserved between different light-emitting units (accompanied by margins for alignment errors). This ensures a degree of overlap between the actual light-emitting area of each light-emitting unit and its intended design location (or design area). In effect, this practice constricts the design area of the light-emitting units, thereby not only restricting the luminous area of individual light-emitting units but also inhibiting a further increase in light-emitting unit arrangement density. Consequently, it poses a challenge to achieving enhanced pixel densities (PPI—pixels per inch) of the display panel.

In the embodiments of the present disclosure, an isolation structure is arranged in the gaps between light-emitting units. This serves to segregate the functional film layers of adjacent light-emitting units. Consequently, during the vapor deposition of these functional layers, it's only necessary to perform whole-surface deposition on the display panel, eliminating the necessity for intricate fine masks to individually deposit layers on each light-emitting unit. This procedure does not have concerns over alignment precision during the vapor deposition process, thereby enabling the design of narrower gaps between light-emitting units, which in turn facilitates an increase in PPI (pixels per inch). The underlying principle is further elucidated in subsequent embodiments related to FIGS. 7 to 10.

In at least one embodiment of the present disclosure, as shown in FIG. 3A and FIG. 3B, the display functional layer includes light-emitting units 200 located in the display area 11a, functioning as the physical luminous entities for the aforementioned sub-pixels R, G, and B. The isolation structure 300 is located in the display area 11a and is an enclosure of a plurality of isolation openings 301, that is, the isolation structure 300 is a mesh-like pattern in plain view, and at least part of the light-emitting unit 200 is located inside the isolation opening 301. At least part of the isolation structure 300 and the charge accumulation structure 300a can be in the same layer and made of the same material. Thus, the charge accumulation structure 300a can be simultaneously fabricated during the fabrication process of the isolation structure 300.

It should be noted that in the embodiments of the present disclosure, “in the same layer and made of the same material” means that both structures are fabricated utilizing at least one same film layer during the same fabricating process.

In at least one embodiment of the present disclosure, as shown in FIG. 3A, an orthogonal projection of an end portion of the isolation structure 300, toward the substrate 100, of the isolation structure 300 on the substrate 100 is located within an orthogonal projection of an end portion of the isolation structure 300, away from the substrate 100, of the isolation structure 300 on the substrate 100. Thus, the isolation structure 300 exhibits a wider width at the top and narrows down towards the bottom, thereby constraining the deposition region of the deposition film layers during the fabrication of light emitting units 200. This measure ensures the electrical performance of the light-emitting units 200 (for instance, the connectivity of the second electrode 230 as detailed in the following) while simultaneously serving to partition certain film layers within the light-emitting units (such as the first luminous functional layer 220 as detailed subsequently). For example, the charge accumulation structure 300a may also be arranged with a wider width at the top and narrower width towards the bottom. That is, an orthogonal projection of an end portion of the charge accumulation structure 300a toward the substrate 100, of the charge accumulation structure 300a on the substrate 100 is located within an orthogonal projection of an end portion of the charge accumulation structure 300a away from the substrate 100, of the charge accumulation structure 300a on the substrate 100.

In at least one embodiment of the present disclosure, as shown in FIG. 3A and FIG. 3B, isolation structure 300 includes a first conductive portion at the end portion of the isolation structure 300 toward the substrate 100 (for example, the first support portion mentioned in the following embodiments), and the light-emitting units 200 includes the first electrode 210 and the first luminous functional layer 220 and the second electrode 230 stacked sequentially on the first electrode 210, the first luminous functional layer 220 and the second electrode 230 are located in the isolation opening 301, and in the display area 11a, the second electrode 230 is connected to the first conductive part. For example, the charge accumulation structure 300a includes a second conductive part at the end portion of the charge accumulation structure 300a toward the substrate 100 (for example, the second support part mentioned in the following embodiments), and the first conductive part and the second conductive part can be in the same layer and made of the same material.

In at least one embodiment of the present disclosure, as shown in FIG. 3A and FIG. 3B, the display panel further includes a second luminous functional layer 220a and a third electrode 230a stacked sequentially on the substrate 100. In transition area 11c, the second luminous functional layer 220a and the third electrode 230a are located in the mesh hole of the charge accumulation structure 300a, and the third electrode 230a is connected to the second conductive part. Thus, the third electrode 230a is configured to cover the mesh hole of the charge accumulation structure 300a, thereby enhancing the charge accumulation capability of the region where the charge accumulation structure 300a is. The second luminous functional layer 220a can be in the same layer and made of the same material as the forementioned first luminous functional layer 220. Similarly, the third electrode 230a can be in the same layer and made of the same material as the forementioned second electrode 230. Thus, during the fabrication process of the light-emitting unit 200, both of the second luminous functional layer 220a and the third electrode 230a can be fabricated simultaneously.

In at least one embodiment of the present disclosure, the first luminous functional layer 220 further includes a first functional layer 221, a luminous layer 222, a second functional layer 223, the first functional layer 221, the luminous layer 222, and the second functional layer 223 are stacked sequentially on the first electrode 210. The first functional layer 221 can include at least one of a hole injection layer, a hole transport layer, and an electron blocking layer. The second functional layer 223 can include at least one of an electron injection layer, an electron transport layer, and a hole blocking layer. It should be noted that since the carrier (including holes and electrons) mainly interferes between adjacent light-emitting units 200 via the first functional layer 221, implementation of the isolation structure 300 is imperative to ensure that the first functional layers 221 of individual light-emitting units 200 is electrically disconnected from each other. Due to the isolation structure 300 characterized by a wider upper section tapering to a narrower base, the first functional layer 221 is disconnected at the edge of the crown portion 320 during vapor deposition. That is, the first functional layer 221 will not be connected to the conductive part (such as the support part 310) of the isolation structure 300 to cause interference between adjacent light-emitting units 200. For example, the second luminous functional layer 220a can further include the forementioned film layers included in the first luminous functional layer 220.

In at least one embodiment of the present disclosure, in the mesh hole of the charge accumulation structure 300a, the luminous layer 222 and/or the second functional layer 223 can be connected to the second conductive part, thereby further improving the charge accumulation capacity of the location where the charge accumulation structure 300a is located.

In the embodiments of the present disclosure, in the case that the isolation structure maintains its characteristic by a wider upper section tapering to a narrower base, the precise isolation structure is not further confined. Subsequent embodiments will elaborate on various configurations and implementation strategies for this isolation structure.

In some embodiments of the present disclosure, as shown in FIG. 3A and FIG. 3B, the isolation structure 300 includes a first support portion 310 and a first crown portion 320, the first support portion 310 is located between the first crown portion 320 and the substrate 100, an orthogonal projection of the first support portion 310 on the substrate 100 is located within an orthogonal projection of the first crown portion 320 on the substrate 100, the charge accumulation structure 300a includes a second support portion 310a and a second crown portion 320a, the second support portion 310a is located between the second crown portion 320a and the substrate 100, and an orthogonal projection of the second support portion 310a on the substrate 100 is located within an orthogonal projection of the second crown portion 320a on the substrate 100. Optionally, at least part of the first support portion 310 and at least part of the second support portion 310a are conductive structures.

For example, the first support portion 310 and the second support portion 310a are in the same layer and made of the same material; and/or, the first crown portion 320 and the second crown portion 320a are in the same layer and made of the same material. Optionally, the first support portion 310 is the first conductive part, and the second support portion 310a is the second conductive part.

For example, in the display panel shown in FIG. 3A and FIG. 3B, the first support portion 310 is fabricated from a conductive material such as metal, and on this basis, the first crown portion 320 is fabricated from a conductive material such as metal, or, the first crown portion 320 is fabricated from an insulating material.

For example, as shown in FIG. 3A and FIG. 3B, in a cross-section orthogonal to the substrate 100, the portion of the first support portion 310 located between adjacent isolation openings 301 exhibits a trapezoidal shape. Configured as a conductive feature of the first support portion 310, the second electrode 230 is connected to the first support portion 310 on the sidewall, thus reducing the requirement for the width difference between the first crown portion 320 and the first support portion 310, thereby decreasing the design width of a part of the isolation structure 300 between the two isolation openings. Consequently, the pixel density, or PPI (Pixels Per Inch), of the display panel is enhanced. Correspondingly, in the case where the isolation structure 300 and the charge accumulation structure 300a are fabricated in the same layer, the second support portion 310a, in a cross-section orthogonal to the substrate 100, also is configured in a trapezoidal cross-sectional shape. Configure the second support portion 310a as a conductive structure, the third electrode 230a is connected to the second support portion 310a on the sidewall.

In at least one embodiment of the present disclosure, the forementioned connection portions can be arranged independently, or, can be arranged in the same layer and made of the same material as at least part of the first support portion 310, and/or, can be arranged in the same layer and made of the same material as the second electrode 230, thereby simplifying the fabrication process of the display panel, to effectively curtail costs.

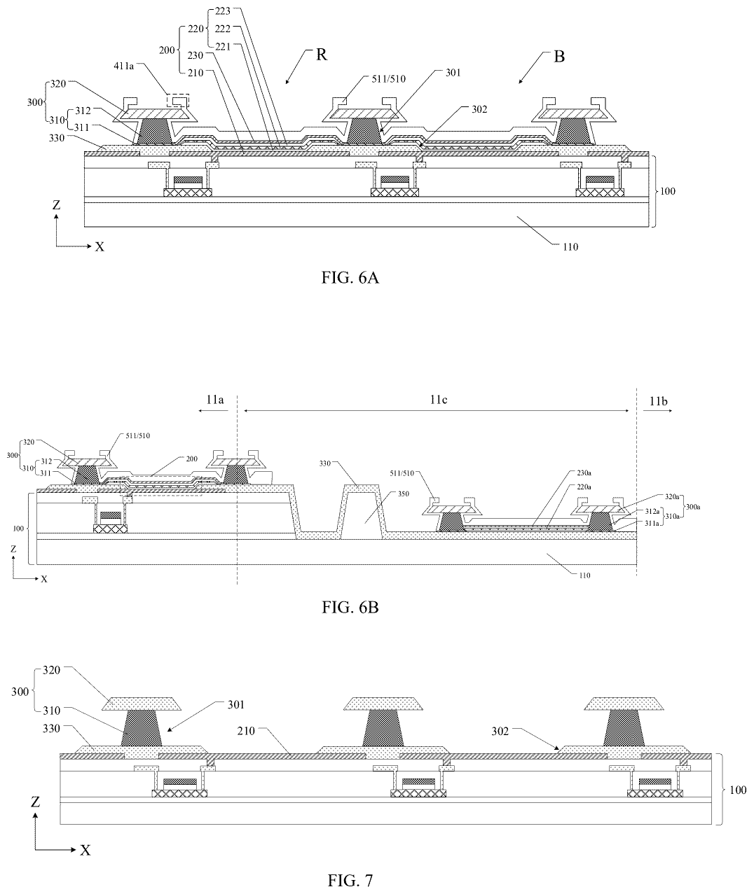

In at least one embodiment of the present disclosure, as shown in FIG. 6A and FIG. 6B, the first support portion 310 can further include a first sub-support layer 311 and a second sub-support layer 312, the first sub-support layer 311 is located between the second sub-support layer 312 and the substrate 100, and the second sub-support layer 312 is located between the first sub-support layer 311 and the first crown portion 320. an orthogonal projection of the second sub-support layer 312 on the substrate 100 is located within an orthogonal projection of the first sub-support layer 311 on the substrate 100; the second support portion 310a can further include a third sub-support layer 311a and a fourth sub-support layer 312a. The third sub-support layer 311a is located between the fourth sub-support layer 312a and the substrate 100, and the fourth sub-support layer 312a is located between the third sub-support layer 311a and the second crown portion 320a. An orthogonal projection of the fourth sub-support layer 312a on the substrate 100 is located within an orthogonal projection of the third sub-support layer 311a on the substrate 100. Thus, the part of the first sub-support layer 311 on the surface away from the substrate 100 that is not covered by the second sub-support layer 312 can be used to make contact with the second electrode 230, and can allow the second electrode 230 to have a greater deposition thickness on the first sub-support layer 311, thereby reducing the resistance at the interface connecting the second electrode 230 to the first support portion 310, Correspondingly, the part of the third sub-support layer 311a on surface away from the substrate 100 that is not covered by the fourth sub-support layer 312a can be used to make contact with the third electrode 230a, and can allow the third electrode 230a to have a greater deposition thickness on the third sub-support layer 311a, thereby reducing the impedance at the interface connecting the third electrode 230a to the third sub-support layer 311a.

It should be noted that in the case that the connection portion is arranged in the same layer and made of the same material as at least part of the first support portion 310, the connection portion can be arranged in the same layer and made of the same material as one of the first sub-support layer 311 and the second sub-support layer 312, or, the connection portion can be arranged in the same layer and made of the same material as the first sub-support layer 311 and the second sub-support layer 312.

For example, the materials of the first sub-support layer 311, the second sub-support layer 312 and the first crown portion 320 are all different. For example, the first sub-support layer 311, the second sub-support layer 312 and the first crown portion 320 can be molybdenum, aluminum, and titanium, respectively. The corrosion resistance of aluminum, molybdenum, and titanium increases in the same order. During etching process, the film layers formed by these materials can form the isolation structure 300 shown in FIG. 6A and FIG. 6B. Correspondingly, the materials of the third sub-support layer 311a, the fourth sub-support layer 312a and the second crown portion 320a are all different. For example, the third sub-support layer 311a, the fourth sub-support layer 312a and the second crown portion 320a can be molybdenum, aluminum, and titanium, respectively. The corrosion resistance of aluminum, molybdenum, and titanium increases in the same order. During etching process, the film layers formed by these materials can form the charge accumulation structure 300a shown in FIG. 6A and FIG. 6B.

In at least one embodiment of the present disclosure, as shown in FIG. 3A and FIG. 3B, in the case where a pixel-defining layer 330 is arranged in the display panel, in the display area, the pixel-defining layer 330 is located between the isolation structure 300 and the substrate 100, and in the transition area 11c, the pixel-defining layer 330 is located between the charge accumulation structure 300a and the substrate 100. In the display area 11a, the pixel-defining layer 330 encloses a plurality of pixel openings 302, and the pixel openings 302 confines the light-emitting units 200. The pixel openings 302 and the isolation openings 301 that confines the same light-emitting unit 200 are interconnected. For example, an orthogonal projection of the pixel opening 302 on the substrate 100 is located within an orthogonal projection of the corresponding isolation opening 301 on the substrate 100, and the first luminous functional layer 220 and the second electrode 230 fill the pixel opening 302 and extend to the pixel-defining layer 330 on surface away from the substrate 100.

It should be noted that in the transition area 11c, the pixel-defining layer 330 maintains a continuous planar configuration without having the pixel openings 302, meaning, an orthogonal projection of the mesh holes in the charge accumulation structure 300a on the base 110 is located within an orthogonal projection of the pixel-defining layer 330 on the base 110.

In at least one embodiment of the present disclosure, the pixel-defining layer 330 includes an inorganic layer. The inorganic layer, characterized by its high density and robust electrical resistivity, allow for a reduction in the design thickness of the display panel; in addition, the reduction in the design thickness of the pixel-defining layer 330 is beneficial to the continuity of the second electrode 230 and the third electrode 230a. For example, the first luminous functional layer 220 and the second electrode 230 of the light-emitting units 200 fabricated by vapor deposition based on the isolation structure 300, and the isolation structure 300 can confine the first luminous functional layer 220 and the second electrode 230. Therefore, the pixel-defining layer 330 doesn't require an excessive thickness dimension to accommodate the first luminous functional layer 220, that is, the pixel-defining layer 330 doesn't need to be fabricated from an organic material with an excessive thickness dimension; in addition, the case that the pixel-defining layer 330 is an inorganic layer, the pixel-defining layer 330 can be thinner, thereby reducing the step difference at the edge of the pixel opening 302 to improve the continuity of the second electrode 230 film layer at the edge, thus reducing the impedance at the connection between the second electrode 230 and the isolation structure 300.

In at least one embodiment of the present disclosure, as shown in FIG. 3A and FIG. 3B, the pixel-defining layer 330 covers the edge of the first electrode 210. Thus, the pixel-defining layer 330 enables a larger design area for the first electrode 210 to increase the emission area of the light-emitting unit 200. For example, in the case where a pixel-defining layer 330 is arranged in a display panel, the first electrode 210 of the light-emitting unit 200 can encompass a substantial area. This approach addresses potential positional misalignments between the first electrode 210 and the isolation structure 300 that may arise due to processing inaccuracy, ensuring a consistent and substantial emission area for the light-emitting units, Consequently, it enhances the aperture ratio (directly tied to the emission area of light-emitting units) and increases the brightness of the displayed imagery on the panel. For example, in the case that not arranging a pixel-defining layer 330, to prevent the connection between the first electrode 210 and the isolation structure 300, the design area of the first electrode 210 must be confined. Misalignment in the placement of the first electrode 210 could result in the actual light-emitting area of the light-emitting units being smaller than what was initially intended in the design, resulting in a decrease of overall emission performance of the light-emitting units.

In at least one embodiment of the present disclosure, re-reference from FIG. 4A and FIG. 4B, in the case that the display panel includes a first encapsulation layer 510, the first encapsulation layer 510 is located in the display functional layer on one side away from the substrate 100 and covers the light-emitting units 200, in order to encapsulate and protecting the light-emitting units 200.

In at least one embodiment of the present disclosure, as shown in FIG. 4A and FIG. 4B, the first encapsulation layer 510 includes a plurality of encapsulation units 511 being spaced apart from each other, and the encapsulation units 511 cover the mesh holes of the isolation openings 301 and the charge accumulation structure 300a. The light-emitting unit 200 is fabrication in batches. During the fabrication of each batch, the encapsulation unit 511 can protect the prepared light-emitting unit 200. Correspondingly, during these fabrication processes, the first encapsulation layer 510 forms a plurality of encapsulation units 511 being spaced apart from each other, and the encapsulation units 511 corresponds respectively to the isolation openings 301 and the mesh holes of the charge accumulation structure 300a to cover and protect the light-emitting units 200 confined within the isolation openings 301 and the third electrodes located in the mesh holes. Optionally, two adjacent encapsulation units 511 located on the same isolation structure 300 are spaced apart.

In at least one embodiment of the present disclosure, as shown in FIG. 3A and FIG. 3B, primarily with the intent of enhancing the encapsulation efficiency, the encapsulation unit 511 can extend to the crown portion (including the first crown portion and the second crown portion) on one side away from the substrate 100. For a detailed understanding of the principle, refer to the pertinent explanations arranged in the embodiments illustrated in FIG. 7 to FIG. 10. In this case, the part of the encapsulation unit 511 that overlaps with the crown portion will form an overhang portion 411a and the overhang portion 411a is set to be spaced apart from the crown portion.

For example, the light-emitting units 200 are classified into light-emitting units that emit red light (R), green light (G), and blue light (B). During the fabrication process, light-emitting units R, G, and B are fabricated in sequence. During the fabrication of light-emitting unit R, each isolation opening 301 accommodates the formation of a respective light-emitting unit R. The first encapsulation layer 510 is fabricated on the display panel to cover light-emitting units R, and then the first encapsulation layer 510, the second electrode and the first luminous functional layer are removed from some parts of isolation openings 301 (intended for the formation of green and blue light-emitting units G, B in the final product). In this process, the first encapsulation layer 510 is used to protect the light-emitting unit R in other isolation openings 301. Based on this method, light-emitting units G, and B are fabricated subsequently, and finally, the first encapsulation layer 510 is formed. That is, the first encapsulation layer 510 on the entire display panel is achieved via a series of sequential processes. The first encapsulation layer 510 further forms a plurality of encapsulation units 511 being spaced apart from each other. In the process, the second luminous functional layer and the third electrode can be fabricated in the mesh holes of the charge accumulation structure 300a during the fabrication of any of the light-emitting units R, G, B; or, the second luminous functional layer and the third electrode can be fabricated in different mesh holes of the charge accumulation structure 300a during the fabrication of any of the light-emitting units R, G, B.

In at least one embodiment of the present disclosure, as shown in FIG. 4A and FIG. 4B, in the case that the display panel includes a second encapsulation layer 520 and a third encapsulation layer 530, in the display area, and the second encapsulation layer 520 is located between the first encapsulation layer 510 and the third encapsulation layer 530 to protect the light-emitting units 200 during encapsulation. The second encapsulation layer 520 is a flat layer so that other components can be arranged on the encapsulation layer 500. For example, The second encapsulation layer 520, fabricated by organic material, providing a certain level of flexibility, thereby serving to alleviate stress of the first encapsulation layer 510 and the third encapsulation layer 530, thereby improving the reliability of the display panel and renders display panel more suitable for application in flexible display technology; in addition, the first encapsulation layer 510 and the third encapsulation layer 530, which are inorganic layers, have high density and provide high barrier properties against ingress of moisture, oxygen, and other substances.

The previous part has briefly described the structure of some components in the display panel. Afterward, there exemplifies the manufacturing method for a display panel, referencing the illustration depicted in FIG. 3A and FIG. 3B.

As shown in FIG. 7 and FIG. 3B, a substrate 100 is arranged and a first electrode 210 arranged in an array is formed on the substrate 100. The first electrode 210 is formed in the display area; an insulating material film layer (e.g., an inorganic material film layer) is deposited on the substrate 100 forming the first electrode 210; a first support portion 310, a first crown portion 320, a second support portion 310a and a second crown portion 320a are formed on the display panel to achieve an isolation structure 300 enclosing isolation openings and a charge accumulation structure 300a with a configuration of mesh holes; the insulating material film layer is patterned to form a pixel-defining layer 330 (having a mesh-like planar shape in the display area), and the pixel-defining layer 330 covers the gaps between adjacent first electrodes 210.

In the embodiments of the present disclosure, the patterning process can be a photo-lithographic patterning process, which can include: applying photo-resist to the structural layer to be patterned; exposing the photo-resist using a mask; processing the exposed photo-resist through developing to yield a photo-resist pattern; using the photo-resist pattern to etch the structural layer (either wet etch or dry etch); and then optionally removing the photo-resist pattern. It should be noted that in the case that the material of the structural layer (e.g., the photo-resist pattern 600 described follow) includes photo-resist, the structural layer can be directly exposed through the mask to form the desired pattern.

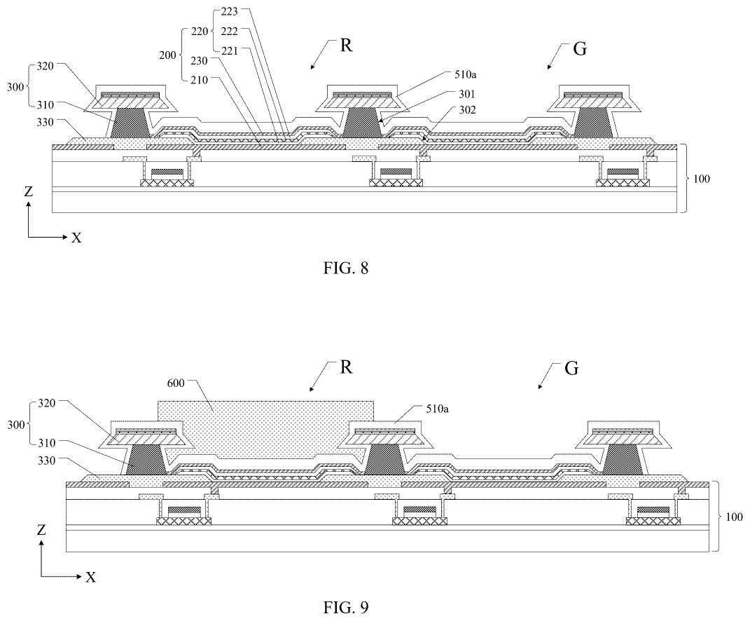

As shown in FIG. 8 and FIG. 3B, the first luminous functional layer 220 and the second electrode 230 are deposited on the substrate 100 to form light-emitting unit 200 (a light-emitting unit R emitting red light) in each isolation opening 301 of the isolation structure 300. In this process, the second luminous functional layer 220a and the third electrode 230a are further formed in the mesh holes. During this process, the deposition process is carried out without employing a mask plate, so the deposited material will further be deposited on the crown portion 320. It should be noted that in the actual process, the deposited material will be deposited on the first crown portion 320 and the second crown 320a in the upper surface away from the substrate 100 and in the sidewalls (not shown in the figure); then a first encapsulation film 510a is deposited to cover the light-emitting units 200, the isolation structure 300 and the charge accumulation structure 300a. For example, the luminous layer in the deposited first luminous functional layer 220 can emit red light.

As shown in FIG. 9 and FIG. 3B, photo-resist is formed (e.g., coated) on the substrate 100 forming the first encapsulation film 510a, and then a patterning process is performed thereon to form a photo-resist pattern 600. The photo-resist pattern 600 only covers a portion of the isolation openings 301 of the isolation structure 300. It should be noted that in case the third electrode 230a formed in the previous progress is to be retained, the photo-resist pattern 600 can be selected to cover the mesh holes; correspondingly, in case the third electrode 230a will be fabricated again in the subsequent process, the photo-resist pattern 600 does not cover the mesh holes in this process.

It should be noted that for fabricating the final display panel, in case the light-emitting units formed in adjacent isolation openings have the same light emission color, the forementioned photo-resist pattern 600 should cover the two adjacent isolation openings and cover the part of the isolation structure located between the two adjacent isolation openings.

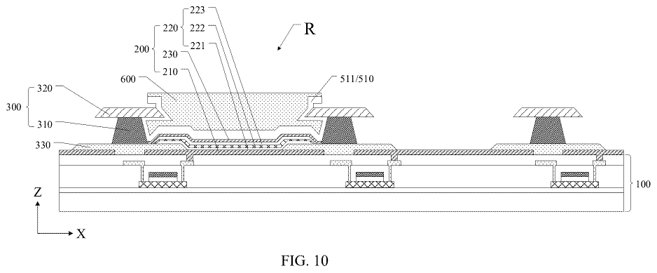

As shown in FIG. 10 and FIG. 3B, in the display area, the display panel is etched on the surface using the photo-resist pattern 600 as a mask to remove the first encapsulation film 510a, the second electrode 230 and the first luminous functional layer 220 that are not covered by the photo-resist pattern 600. The remaining part of the first encapsulation film 510a forms the first encapsulation layer 510 (including the encapsulation units 511); then the residual photo-resist pattern 600 is removed. It should be noted that in this process, in case the third electrode in the mesh holes is selected to be removed, and the photo-resist pattern 600 does not cover the third electrode, then the second luminous functional layer and the third electrode will further be removed in this etching process.

The forementioned processes are repeated to form light-emitting units 200 emitting green light and light-emitting units 200 emitting blue light in other isolation openings 301, respectively, to form the display panel shown in FIG. 3A and FIG. 3B.

In some embodiments of the present disclosure, the charge accumulation structure can be arranged independently to only accumulate charge and disperse the distribution of charge, thus mitigating the likelihood of electrostatic discharge incidents arising from accumulated static charges. In this case, it is not necessary to externally discharge the accumulated static charge. In addition, this design can reduce or avoid the wiring layout (e.g., wires described follow) in the transition area, thereby enhancing the encapsulation efficiency in the transition area.

In some other embodiments of the present disclosure, wires can be additionally arranged in the display panel to extend into the transition area to connect with the charge accumulation structure, thereby externally discharging the charge accumulated by the charge accumulation structure. For example, a ground wire can be arranged in the display panel, and the wire can be connected to the ground.

In some other embodiments of the present disclosure, an electrostatic shielding layer and/or a structure for discharging static electricity (e.g., a support frame (or housing) anchorage on the exterior of the display panel) can be arranged in the display panel. The charge accumulation structure can be electrically connected to the electrostatic shielding layer and/or the structure to externally discharge the accumulated charge.

In at least one embodiment of the present disclosure, the display panel can further include a touch structure, an optical film (e.g., a micro-lens, a polarizer), a color filter, a cover plate, etc. on the light emission side.

For example, in the case that the display panel includes the third encapsulation layer forementioned, the touch structure can be located in the third encapsulation layer on one side away from the substrate and located in the display area. For example, the touch structure can be directly formed on the third encapsulation layer, or a buffer layer can be formed on the third encapsulation layer, and then the touch structure can be formed on the buffer layer.

For example, the optical film can include micro-lenses located in the display area. The micro-lenses can be located in the third encapsulation layer on one side away from the substrate, or located between the first encapsulation layer and the third encapsulation layer.

For example, the color filter located in the display area can be located in the third encapsulation layer on one side away from the substrate, or located between the first encapsulation layer and the third encapsulation layer.

At least one embodiment of the present disclosure provides another display panel, which can be specifically referred to FIG. 1 to FIG. 6. The display panel 10 includes a display area 11a, an opening area 11b, and at least one transition area 11c located between the display area 11a and the opening area 11b. Specifically, the display panel 10 includes: a substrate 100, a charge accumulation structure 300a, a display functional layer and an isolation structure 300. Specifically, the charge accumulation structure 300a is located on the substrate 100 and is located in the transition area 11c. Specifically, the charge accumulation structure 300a surrounds at least part of the opening area 11b and is at least partially a conductive structure. The display functional layer is located on the substrate 100 and includes light-emitting units 200 located in the display area 11a. The isolation structure 300 is located in the display area 11a and is located on the substrate 100. The isolation structure 300 encloses a plurality of isolation openings 301, and at least part of the light-emitting unit 200 is located within the isolation opening 301.

Optionally, the isolation structure 300 includes a first support portion 310 and a first crown portion 320. The first support portion 310 is located between the first crown portion 320 and the substrate 100. An orthogonal projection of the first support portion 310 on the substrate 100 is located within an orthogonal projection of the first crown portion 320 on the substrate 100. The charge accumulation structure 300a includes a second support portion 310a and a second crown portion 320a. The second support portion 310a is located between the second crown portion 320a and the substrate 100, and an orthogonal projection of the second support portion 310a on the substrate 100 is located within an orthogonal projection of the second crown portion 320a on the substrate 100.

Optionally, the first support portion 310 and the second support portion 310a are in the same layer and made of the same material; and/or, the first crown portion 320 and the second crown portion 320a are in the same layer and made of the same material.

At least one embodiment of the present disclosure provides a display device that includes the display panel of the forementioned embodiments. For example, the display device encompasses any merchandise or component capable of displaying visuals, encompassing but not limited to televisions, digital cameras, mobile phones, smartwatches, tablets, laptops, GPS navigators, among others.

The aforementioned constitutes merely the preferred embodiment for executing the invention and is not intended to restrict its scope. Any adjustments or equivalent substitutions that adhere to the spirit and principles of the invention are intended to fall within the scope of the patent claims.

What is claimed is:

1. A display panel, comprising a display area, an aperture area, and at least one transition area located between the display area and the aperture area, wherein the display panel further comprises:
a substrate; and
a charge accumulation structure located on the substrate and within the at least one transition area, wherein the charge accumulation structure surrounds at least a portion of the aperture area and is at least partially conductive.

2. The display panel according to claim 1, wherein
the substrate comprises a base and a driver circuit layer located on the base, at least a portion of the driver circuit layer is located in the display area, and the charge accumulation structure is located on the base, and
the charge accumulation structure surrounds the aperture area.

3. The display panel according to claim 2, wherein
the charge accumulation structure comprises a plurality of sub-charge accumulation portions, and the plurality of sub-charge accumulation portions are spaced apart from each other and surround the aperture area sequentially along a direction away from the aperture area.

4. The display panel according to claim 3, wherein
the charge accumulation structure further comprises at least one connecting portion, the at least one connecting portion is conductive, and each connecting portion of the at least one connecting portion is located between adjacent sub-charge accumulation portions of the plurality of sub-charge accumulation portions and is connected to the sub-charge accumulation portions adjacent to the connecting portion.

5. The display panel according to claim 3, wherein
the sub-charge accumulation portions comprise a mesh-like structure.

6. The display panel according to claim 3, further comprising a first encapsulation layer, a second encapsulation layer, and a third encapsulation layer stacked on the substrate sequentially,
wherein each of the first encapsulation layer and the third encapsulation layer comprises an inorganic layer, the second encapsulation layer comprises an organic layer, the first encapsulation layer and the second encapsulation layer are located in the display area and in the at least one transition area, the third encapsulation layer is located in the display area and in the at least one transition area, and
the third encapsulation layer covers the charge accumulation structure on one side, away from the substrate, of the charge accumulation structure and covers a gap between each two of the plurality of the sub-charge accumulation portions.

7. The display panel according to claim 6, further comprising:
a pixel-defining layer, located in the display area and the at least one transition area;
wherein within the transition area, the pixel-defining layer is located between the charge accumulation structure and the base, and the pixel-defining layer comprises an inorganic layer, and
the third encapsulation layer is in contact with the pixel-defining layer at the gaps between adjacent sub-charge accumulation portions of the plurality of the sub-charge accumulation portions.

8. The display panel according to claim 7, further comprising at least one dam, wherein the at least one dam is located between the display area and the charge accumulation structure, and is located between the substrate and the pixel-defining layer.

9. The display panel according to claim 1, further comprising:
a display function layer, located on the substrate and comprising a plurality of light-emitting units located in the display area; and
an isolation structure, located in the display area and located on the substrate;
a plurality of isolated openings encircled by the isolation structure enclosing, and at least a portion of each of the plurality of light-emitting units being located within the plurality of isolated openings.

10. The display panel according to claim 9, wherein
the isolation structure and at least a portion of the charge accumulation structure are in the same layer and made of the same material.

11. The display panel according to claim 10, wherein
an orthogonal projection of an end portion, toward the substrate, of the isolation structure on the substrate is located within an orthogonal projection of an end portion, away from the substrate, of the isolation structure on the substrate; and,
an orthogonal projection of an end portion, toward the substrate, of the charge accumulation structure on the substrate is located within an orthogonal projection of an end portion, away from the substrate, of the charge accumulation structure on the substrate.

12. The display panel according to claim 11, wherein
the isolation structure comprises a first support portion and a first crown portion, the first support portion is located between the first crown portion and the substrate, and an orthogonal projection of the first support portion on the substrate is located within an orthogonal projection of the first crown portion on the substrate;
the charge accumulation structure comprises a second support portion and a second crown portion, the second support portion is located between the second crown portion and the substrate, and an orthogonal projection of the second support portion on the substrate is located within an orthogonal projection of the second crown portion on the substrate;
at least a portion of each of the first support portion and the second support portion is a conductive structure; and
the first support portion and the second support portion are in a same layer and made of same material; and, the first crown portion and the second crown portion are in a same layer and made of same material.

13. The display panel according to claim 12, wherein
each of the plurality of light-emitting units comprises a first electrode, a first light-emitting function layer, and a second electrode stacked sequentially on the substrate, the first light-emitting function layer and the second electrode are located within the plurality of isolated openings, and
the second electrode is connected to the first support portion.

14. The display panel according to claim 13, wherein
the charge accumulation structure comprises a plurality of sub-charge accumulation portions, the plurality of sub-charge accumulation portions are spaced apart from each other and surrounding the aperture area sequentially along a direction away from the aperture area, the plurality of sub-charge accumulation portions comprise a mesh-like structure, and
a second light-emitting functional layer and a third electrode are disposed in each of mesh holes of the mesh-like structure of each of the plurality of sub-charge accumulation portions, and the third electrode is connected to the second support portion.

15. The display panel according to claim 14, wherein
the charge accumulation structure further comprises at least one connecting portion, the at least one connecting portion is conductive, and each connecting portion of the at least one connecting portion is located between adjacent sub-charge accumulation portions of the plurality of sub-charge accumulation portions and is connected to the sub-charge accumulation portions adjacent to the connecting portion.

16. The display panel according to claim 14,
further comprising a first encapsulation layer covering the isolation structure and the charge accumulation structure,
wherein the first encapsulation layer comprises a plurality of encapsulation units spaced-apart each other, the encapsulation units correspond to the isolated openings and the mesh hole respectively, and cover the isolated openings and the mesh hole corresponding to the encapsulation units.

17. The display panel according to claim 12, wherein
the first support portion comprises a first sub-support layer and a second sub-support layer, the first sub-support layer is located between the second sub-support layer and the substrate, the second sub-support layer is located between the first sub-support layer and the first crown portion, and an orthogonal projection of the second sub-support layer on the substrate is located within an orthogonal projection of the first sub-support layer on the substrate; and
the second support portion comprises a third sub-support layer and a fourth sub-support layer, the third sub-support layer is located between the fourth sub-support layer and the substrate, the fourth sub-support layer is located between the third sub-support layer and the second crown portion, and an orthogonal projection of the fourth sub-support layer on the substrate is located within an orthogonal projection of the third sub-support layer on the substrate.

18. The display panel according to claim 11, further comprising:
a pixel-defining layer being located in the display area and in the transition area, wherein the pixel-defining layer is located between the isolation structure and the substrate, and the pixel-defining layer is located between the charge accumulation structure and the substrate;
wherein, in the display area, the pixel-defining layer enclosures a plurality of pixel openings, at least some of the plurality of pixel openings delimit the light-emitting units, and the pixel openings and the isolated openings delimit the same light-emitting units are connected to each other.

19. A display panel, comprising a display area, an aperture area, and at least one transition area located between the display area and the aperture area, wherein the display panel further comprises:
a substrate;
a charge accumulation structure located on the substrate and within the at least one transition area, wherein the charge accumulation structure surrounds at least a portion of the aperture area and is at least partially conductive;
a display function layer located on the substrate and comprised a plurality of light-emitting units located in the display area; and
an isolation structure located in the display area and on the substrate;
a plurality of isolated openings encircled by the isolation structure enclosing, and at least a portion of each of the plurality of light-emitting units located within the plurality of isolated openings.

20. A display device, comprising a display panel according to claim 1.
